(19) United States
(12) Patent Application Publication
(10) Pub. No.: US 2024/0258177 A1
(43) Pub. Date: Aug. 1, 2024

(54) METHODS FOR CORRECTING WARPAGE WITH STRESS FILMS AND PACKAGE STRUCTURES THEREOF

(71) Applicant: TAIWAN SEMICONDUCTOR MANUFACTURING COMPANY, LTD., Hsinchu (TW)

(72) Inventors: Tsung-Chieh HSIAO, Changhua (TW); Chih Hsin YANG, Hsinchu (TW); Dian-Hau CHEN, Hsinchu (TW)

(21) Appl. No.: 18/103,846

(22) Filed: Jan. 31, 2023

(51) Int. Cl. H01L 21/66; H01L 23/00; H01L 23/48; H01L 23/538

(52) U.S. Cl. CPC H01L 22/12; H01L 23/481; H01L 23/5389; H01L 23/562

(57) ABSTRACT

Embodiments of the present disclosure relate to methods for warpage correction. Particularly, embodiments of the present disclosure relate to substrate level warpage correction by depositing one or more warpage correction layers in a redistribution layer (RDL) structure, a front side warpage correction layer, and/or a back side warpage correction layer. In some embodiments, the warpage correction layer is a high stress dielectric layer. Characteristics of the warpage correction layer, such as stress level, and thickness, may be determined according to the substrate level warpage and the die level packaging scheme using an auto process control program.

### BACKGROUND

Semiconductor devices are used in a variety of electronic applications, such as personal computers, cell phones, digital cameras, and other electronic equipment, as examples. Semiconductor devices are typically fabricated by sequentially depositing various insulating or dielectric layers, conductive layers, and semiconductive layers of material over a semiconductor substrate, and patterning the various material layers using lithography to form circuit components and elements thereon. Dozens or hundreds of integrated circuits are typically manufactured on a single semiconductor substrate. The individual dies are singulated by sawing the integrated circuits along a scribe line. The individual dies are then packaged separately, in multi-chip modules, or in other types of packaging, for example.

The semiconductor industry continues to improve the integration density of various electronic components by continual reductions in minimum feature size, which allow more components to be integrated into a given area. These smaller electronic components require smaller and more advanced packaging systems than packages of the past, in some applications. Additionally, as more and more metal layers adding into the advanced BEOL (back end of line) processing, SOC (system on a chip) substrate warpage becomes higher and higher, which significantly degrades SoIC (system on integrated circuit) chip-on-substrate process window and result in bond low yield.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic cross sectional view of a device substrate with positive warpage.

FIG. 1B is s schematic cross sectional view of the device substrate of FIG. 1A after warpage correction using high stress films.

FIG. 1C is a schematic cross sectional view of a device substrate with a negative warpage.

FIG. 1D is s schematic cross sectional view of the device substrate of FIG. 1C after warpage correction using high stress films.

FIG. 2 is a flow chart of a method for correcting warpage during formation of RDL (redistribution layer).

FIGS. 3A-3F are schematic partial cross section of a device substrate at various stages form RDL.

FIG. 4 is a flow chart of a method for correcting warpage using a front side stress layer.

FIGS. 5A-5D are schematic partial cross section of a device substrate at various stages forming a front side stress layer.

FIG. 6 is a flow chart of a method for correcting warpage using a back side stress layer.

FIG. 7 is schematic partial cross section of a device substrate with a back side stress layer.

FIG. 8A is a package structure formed by a system on chip (SOC) packaging scheme.

FIGS. 8B and 8C are schematically illustrate warpage correction plans for the SOC packaging scheme.

FIG. 9A is a package structure formed by a SoIC (an integrated SOC) packaging scheme.

FIGS. 9B-9D are schematically illustrate warpage correction plans for the SoIC packaging scheme.

FIG. 10 is a package structure formed by a SoIC (an integrated SOC) packaging scheme.

FIGS. 10B-10D are schematically illustrate warpage correction plans for the SoIC packaging scheme.

FIG. 11 is flow chart of a method for warpage correction at substrate level for dies to be packaged with a SOC packaging scheme.

FIG. 12 is flow chart of a method for warpage correction at substrate level for dies to be packaged with a SIoC packaging scheme.

FIG. 13 is a schematic cross sectional view of a SoIC package structure including dies with warpage correcting layers according to embodiments of the present disclosure.

FIG. 14 is a schematic cross sectional view of a SoIC package structure including dies with warpage correcting layers according to embodiments of the present disclosure.

FIG. 15 is a schematic plot warpage measurement during warpage correction according to embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 64 degrees or at other orientations) and the spatially relative descriptors used herein may likewise be interpreted accordingly.

Embodiments of the present disclosure relate to methods for warpage correction. Particularly, embodiments of the present disclosure relate to substrate level warpage correction by depositing one or more warpage correction layers in a redistribution layer (RDL) structure, a front side warpage correction layer, and/or a back side warpage correction layer. In some embodiments, the warpage correction layer is a high stress dielectric layer. Characteristics of the warpage correction layer, such as stress level, and thickness, may be determined according to the substrate level warpage and the die level packaging scheme using an auto process control program.

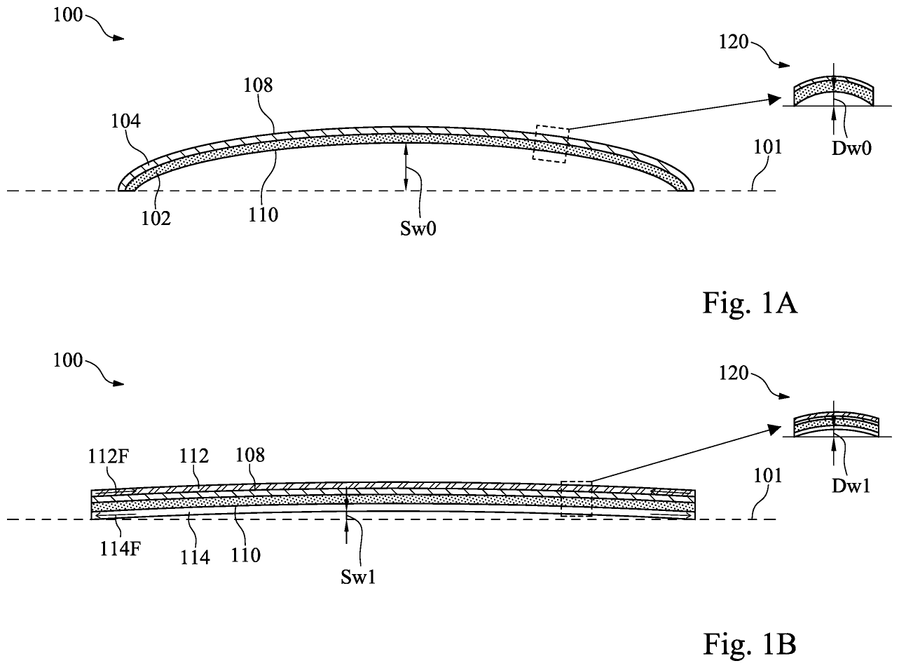

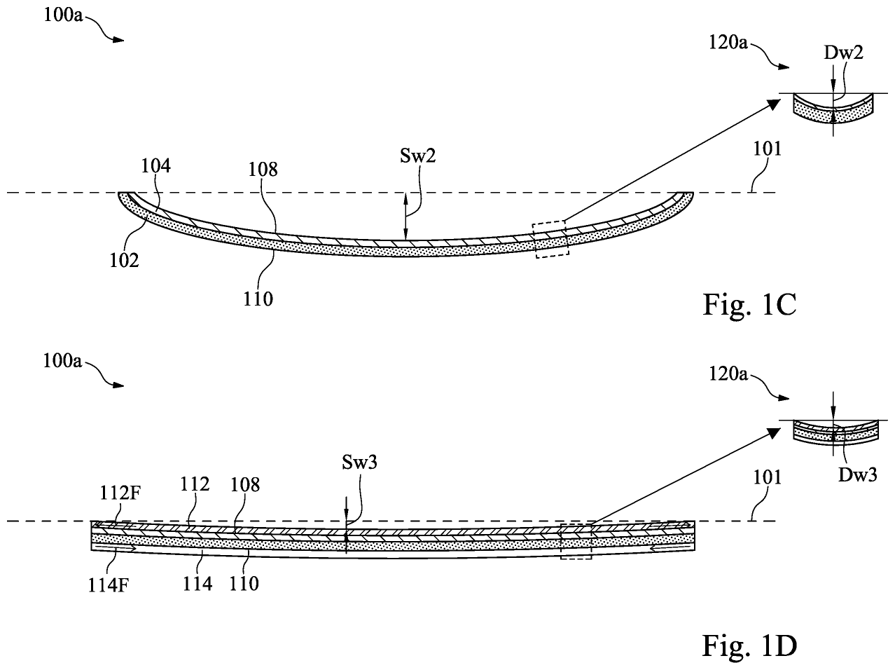

FIG. 1A is a schematic cross sectional view of a device substrate 100 with a positive warpage. The device substrate 100 may include a device layer 104 formed on a substrate 102. The device layer 104 may be fabricated on the substrate 102 by front-end-of-line (FEOL) processes, middle-end-of-line (MEOL) processes, and back-end-of-line (BEOL) processes. In some embodiments, the device layer 104 may include various devices, such as transistors, capacitors, resistors, and the like, formed in and on the substrate 102, and an interconnect structure formed over the various devices. The device layer 104, the device substrate 100 is diced into individual dies 120 for packaging. FIG. 1A includes a schematically enlarged view of a die 120.

As schematically shown in FIG. 1A, the device substrate 100 is warped after fabrication. Particularly, the device substrate 100 is warped that the front surface 108 is convex and the back surface 110 is concave. In some embodiments, warpage of the device substrate 100 may be quantified by a maximum distance between the device substrate 100 and the horizontal plane 101 when positioned with the device layer 104 facing up. As shown in FIG. 1A, a substrate level warpage Sw0 of the device substrate 100 is denoted by a maximum distance between the back surface 110 and the horizontal plane 101. The back surface 110 is above the horizontal plane 101 resulting in a positive warpage. Similarly, the individual die 120 has a die level warpage Dw0. The die level warpage Dw0 is proportional to the substrate level warpage Sw0, and may be calculated from the substrate level warpage Sw0 according to the size of the individual die 120 and the size of the device substrate 100.

The die level warpage Dw0 affects the quality of the packaging structure. For example, depending on the packaging scheme under which the individual die 120 is to be packaged, the die level warpage Dw0 may be within a particular warpage tolerance to achieve desired quality. If the die level warpage Dw0 is outside the warpage tolerance, warpage correction may be made at the substrate level. In some embodiments, after fabrication of the device substrate 100, the substrate level warpage Sw0 may be measured, and one or more warpage correction films may be formed on the device substrate 100 if needed.

FIG. 1B is s schematic cross sectional view of the device substrate 100 of FIG. 1A after warpage correction using high stress films. According to embodiments of the present disclosure, one or both warpage correction films 112, 114 may be formed on the device substrate 100. The warpage correction film 112 is formed on the front side 108 of the device substrate 100. The warpage correction film 112 may be a high stress dielectric with stress 112F. The stress 112F in the warpage correction film 112 is a tensile stress so that the warpage correction film 112 reduces positive warpage in the device substrate 100. In some embodiments, the front side warpage correction film 112 may be one or more high stress dielectric films in a RDL structure. In some embodiments the front side warpage correction film 112 may be a high stress dielectric film formed on the RDL structure. The warpage correction film 114 is formed on the back side 110 of the device substrate 100. In some embodiments, the back side warpage correction film 114 is one or more high-stress dielectric layers formed on the back side of the substrate 102. The warpage correction film 114 may be a high stress dielectric with stress 114F in the warpage correction film 114. The stress 114F is a compressive stress so that the warpage correction film 114 reduces the positive warpage in the device substrate 100 from the back side of the device substrate 100.

As shown in FIG. 1B, after the warpage correction films 112, 114 are formed on the device substrate 100, the substrate level warpage is reduced from the warpage Sw0 to Sw1, and the die level warpage is reduced from Dw0 to Dw1.

FIG. 1C is a schematic cross sectional view of a device substrate 100a with a negative warpage. The device substrate 100a is similar to the device substrate 100 except that the device substrate 100a has a negative warpage. Particularly, the device substrate 100a is warped that the front surface 108 is concave and the back surface 110 is convex. The warpage of the device substrate 100a may be quantified by a maximum distance between the device substrate 100 and the horizontal plane 101 when positioned with the device layer 104 facing up. As shown in FIG. 1C, a substrate level warpage Sw2 of the device substrate 100a is denoted by a maximum distance between the front surface 108 and the horizontal plane 101. The front surface 108 is below the horizontal plane 101 resulting in a negative warpage. Similarly, the individual die 120a has a die level warpage Dw2. The die level warpage Dw2 is proportional to the substrate level warpage Sw2, and may be calculated from the substrate level warpage Sw2 according to the size of the individual die 120a and the size of the device substrate 100a.

If the die level warpage Dw2 is outside the warpage tolerance, warpage correction may be made at the substrate level. In some embodiments, after fabrication of the device substrate 100a, the substrate level warpage Sw2 may be measured, and one or more warpage correction films may be formed on the device substrate 100a if needed.

FIG. 1D is s schematic cross sectional view of the device substrate 100a of FIG. 1C after warpage correction using high stress films. According to embodiments of the present disclosure, one or both warpage correction films 112, 114 may be formed on the device substrate 100a. The stress 112F in the front side warpage correction film 112 is a compressive stress so that the warpage correction film 112 reduces negative warpage in the device substrate 100a. The stress 114F in the back side warpage correction film 114 is a tensile stress so that the warpage correction film 114 reduces the positive warpage in the device substrate 100 from the back side of the device substrate 100a.

As shown in FIG. 1D, after the warpage correction films 112, 114 are formed on the device substrate 100a, the substrate level warpage is reduced from the warpage Sw2 to Sw3, and the die level warpage is reduced from Dw2 to Dw3.

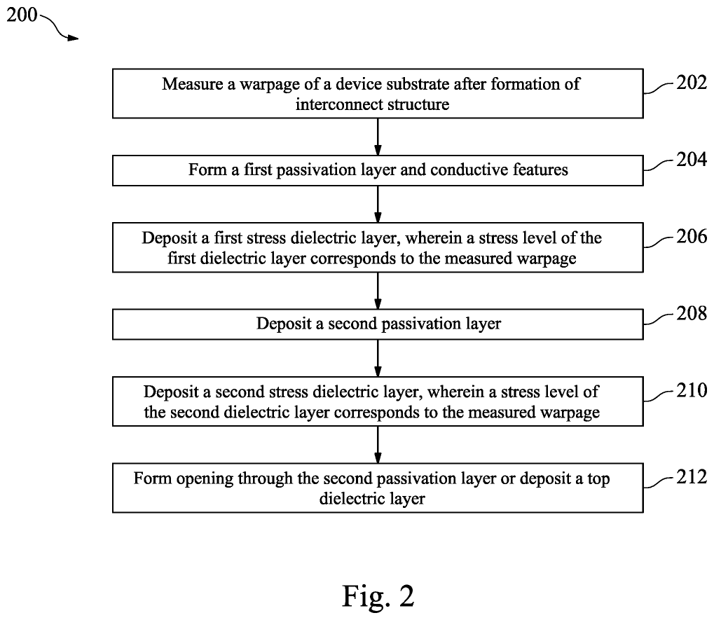

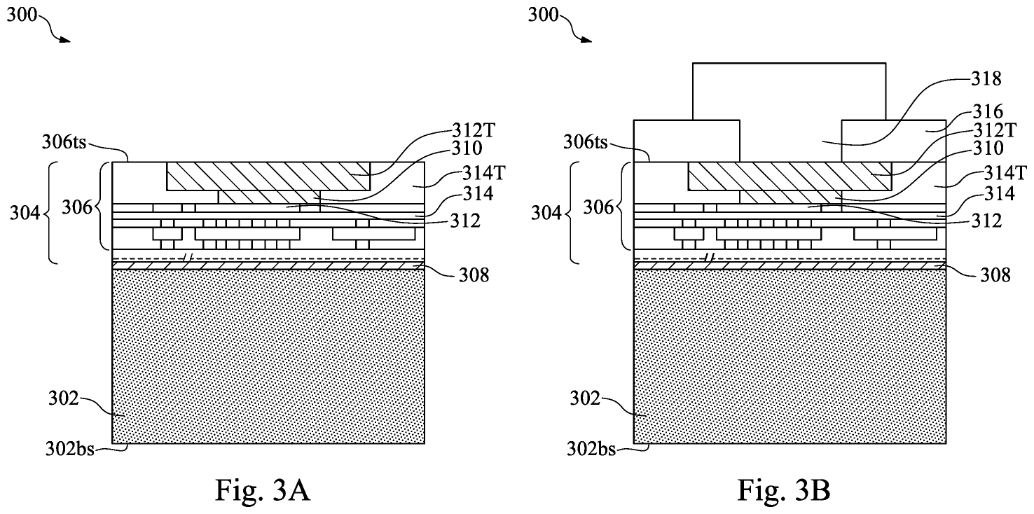

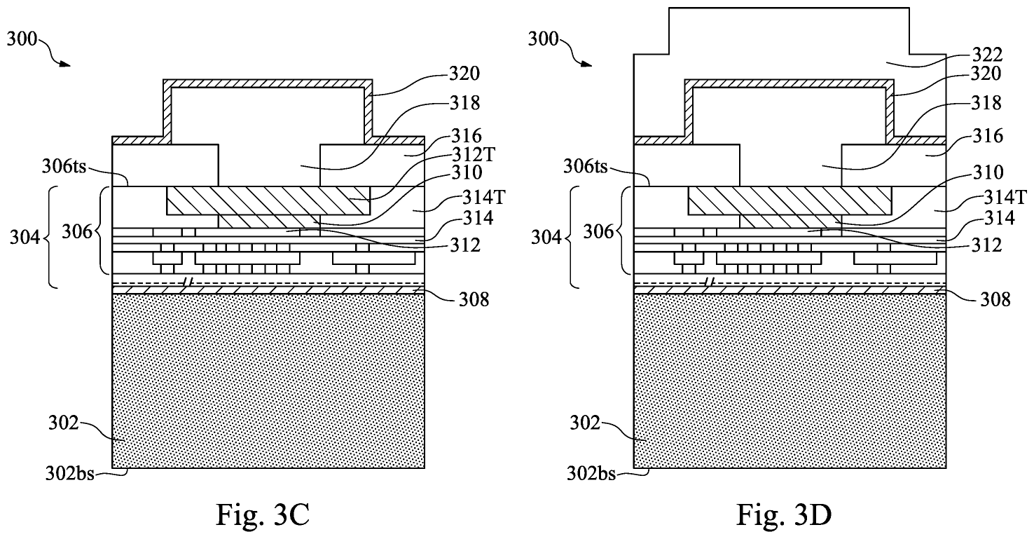

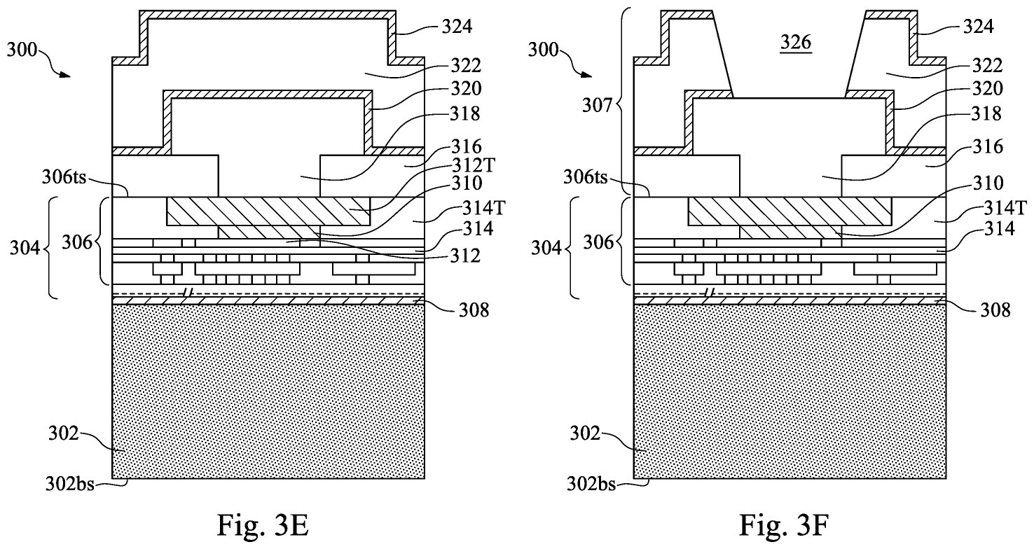

FIG. 2 is a flow chart of a method 200 for correcting warpage during formation of RDL (redistribution layer) structure. FIGS. 3A-3F are schematic partial cross section of a device substrate 300 at various stages of forming a RDL structure using the method 200.

In operation 202, warpage of the device substrate 300 is measured. As shown in FIG. 3A, the device substrate 300 includes a device portion 304 formed on a substrate 302. In some embodiments, the device portion 304 may include device layer 308, complementary Metal-Oxide Semiconductor (CMOS) transistors, resistors, capacitors, diodes, and the like, formed in and on a top surface of the substrate 302, and an interconnect structure 306 formed over the device layer 308.

The interconnect structure 306 includes multiple levels of conductive features 310 and 312 formed in metal dielectric (IMD) layers 314. Barrier layers, not shown, may be formed between the conductive features 310, 312 and the IMD layers 314. The conductive features 310 and 312 may be formed level by level using suitable metallization processes, such as damascene process. The conductive features 310 may be conductive vias and the conductive features 312 may be conductive lines. The conductive features 312 in different level of the IMD layers 314 are interconnected through the conductive features 310. The conductive features 310 and 312 may be formed of copper, copper alloys, or other suitable metals. The IMD layers 314 are formed of low-k dielectric materials, such as dielectric materials with dielectric constants (k values) lower than about 3.0. The IMD layers 314 may comprise a carbon-containing low-k dielectric material, Hydrogen SilsesQuioxane (HSQ), MethylSilsesQuioxane (MSQ), or the like.

The formation of the conductive features 310 and 312 in the IMD layers 314 may include single damascene processes and/or dual damascene processes. In a single damascene process for forming a metal line or a via, a trench or a via opening is first formed in one of the IMD layers 314, followed by filling the trench or the via opening with a conductive material. A planarization process such as a Chemical Mechanical Polish (CMP) process is then performed to remove the excess portions of the conductive material higher than the top surface of the dielectric layer, leaving a metal line or a via in the corresponding trench or via opening. In a dual damascene process, both of a trench and a via opening are formed in a dielectric layer, with the via opening underlying and connected to the trench. Conductive materials are then filled into the trench and the via opening to form a metal line and a via, respectively. The conductive materials may include a diffusion barrier layer and a copper-containing metallic material over the diffusion barrier layer. The diffusion barrier layer may include titanium, titanium nitride, tantalum, tantalum nitride, or the like.

The interconnect structure 306 has a top surface 306ts resulting from a planarization process of the top IMD layer 314T. The top surface 306ts may include areas of the top conductive features 312T, the IMD layer 314, and the barrier layer if present. The device substrate 300 has a back surface 302bs. After formation of the device portion 304 on the substrate 302, the device substrate 300 may be warped. Various factors, such as circuit designs and processes of the device portion 304, may affect the amount and direction of warpage of the device substrate 300.

In some embodiments, the amount and direction of warpage may be measured by a maximum distance between the top surface 306ts or the back surface 302bs the device substrate 300 deviates from a horizontal plane. In some embodiments, warpage measurement may be performed in line, for example using probes in processing chambers or tools. In some embodiments, the warpage measurement may be used to determine die level warpage. If the measured die level warpage is greater than the warpage tolerance of the corresponding packaging scheme. In some embodiments, characteristics of the warpage correction films are determined according to the measured warpage so that the die level warpage is within the warpage tolerance.

In operation 204, a first passivation layer 316 and conductive pads 318 are formed over the interconnect structure 306, as shown in FIG. 3B. The first passivation layer 316 is sometimes referred to as passivation-1 or pass-1. In some embodiments, the first passivation layer 316 is formed of a non-low-k dielectric material with a dielectric constant greater than the dielectric constant of silicon oxide. The first passivation layer 316 may be formed of or comprise an inorganic dielectric material, which may include a material selected from, and is not limited to, silicon nitride (SiNₓ), silicon oxide (SiO₂), silicon oxy-nitride (SiONₓ), silicon oxy-carbide (SiOCₓ), silicon carbide (SiC), or the like, combinations thereof, and multi-layers thereof. The value “x” represents the relative atomic ratio. In some embodiments, an etch stop layer, not shown, may formed over the top surface 306ts prior to formation of the first passivation layer 316. The etch stop layer may include a dielectric material having an etch selectivity over the first passivation layer 316 and the top conductive features 312T. In some embodiments, the etch stop layer may include SiNx, SiCxNy, AlNx, AlOx, AOxNy, SiOx, SiCx, SiOxCy, or other suitable materials.

The first passivation layer 316 is patterned in an etching process to form openings to expose the top conductive features 312T. The conductive pad 318 is formed on and penetrating through the first passivation layer 316 to electrically connect to the top conductive feature 312T of the interconnection structure 306, and further electrically connected to the device layer 308 through the interconnection structure 306. The conductive pad 318 includes conductive materials such as metal or metal alloy, such as aluminum, copper, nickel, or alloys thereof. In some embodiments, the conductive pad 318 is a copper aluminum pad. In some embodiments, the conductive pad 318 includes a via portion embedded in and penetrating through the first passivation layer 316 to be in electrical and physical contact with the topmost conductive feature 312T of the interconnection structure 306, and a protruding portion on the via portion and the first passivation layer 316.

In operation 206, a first stress dielectric layer 320 is deposited on the first passivation layer 316 and the conductive pads 318, as shown in FIG. 3C. As discussed above, a stress level of the first dielectric layer 320 corresponds to the measured warpage. The first stress dielectric layer 320 is formed to create desirable stress and transfer the stress to the underlying features/layers. When the measured warpage indicates that the device substrate 300 needs warpage correction, the first stress dielectric layer 320 may be formed with a stress level to reduce warpage by imparting a stress/strain in the device substrate 300, thus, functioning as a warpage correction film. When the measured warpage indicates that the device substrate 300 does not need warpage correction, the first stress dielectric layer 320 may be formed with normal stress so that the dielectric layer 320 to function as an etch stop layer for in subsequent processes.

In some embodiments, the first stress dielectric layer 320 may silicon nitride (Si₃N₄ or SiN), tetraethylorthosilicate (TEOS), silicon oxide, silicon oxynitride (SiON), Si-rich silicon nitride, a N-rich silicon nitride, or a combination. A process used to form the first stress dielectric layer 320 may include plasma enhanced chemical vapor deposition (PECVD), low pressure chemical vapor deposition (LPCVD), atomic layer deposition (ALD), rapid thermal chemical vapor deposition (RTCVD), physical vapor deposition (PVD), individually or in combination. The first stress dielectric layer 320 may be a compressive stress film or a tensile stress film according to warpage correction needs. The stress level may be tuned by changing one or more of process factors, including but not limited to, composition, thickness, processing conditions, such as plasm power, pressure, temperature, and the like. The first stress dielectric layer 320 may comprise a single layer or a plurality of layers.

In some embodiments, the first stress dielectric layer 320 may function as an etch stop layer. The first stress dielectric layer 320 may have a thickness in a range between about 5 nm and 500 nm. In some embodiments, the first stress dielectric layer 320 may comprise silicon nitride. Stoichiometric silicon nitride films are known to be highly tensile stressed on various materials, such as silicon. In some embodiments, the tensile stress may be greatly lowered and even turned into compressive stress by adjusting the film density. Plasma-enhanced chemical vapor deposition (PECVD) has been used for the deposition of stress films, such as SiNₓ, because PECVD allows tuning of the properties of the stress films by changing the deposition conditions. Mechanism of changing the mechanical properties can be extended to fabricate mechanically robust SiNₓ thin films as dielectric layers for flexible devices. For example, SiNₓ thin films are prepared using three types of PECVD conditions to induce tensile (T-SiNₓ), neutral (N—SiNₓ), and compressive (C-SiNₓ) residual stress. Compared with the T-SiNₓ thin films (77 GPa, 0.10%, and 83 MPa, respectively), the C—SiNₓ thin films shows an approximately 45% increase in Young's modulus (112 GPa), a twofold enhancement of the elongation (0.21%), and a threefold improvement in the fracture strength (226 MPa). Thus, C—SiNₓ thin films have improved intrinsic mechanical properties. In some embodiments, higher RF power, lower chamber pressure, and/or lower NH₃ feed ratios are used to deposition C—SiNₓ thin films increase film density, for example from, 2.42-2.64 g/cm³, and reduce dangling H of the N—H bonding.

The first stress dielectric layer 320 when compressive is preferably comprised of silicon nitride (Si₃N₄ or SiN), silicon oxynitride (SiON), oxide, a Si-rich nitride, or a N-rich nitride. The first stress dielectric layer 320 may be SiN or SiON and is most preferably SiON. The first stress dielectric layer 320 may be deposited by plasma enhanced chemical vapor deposition (PECVD). PECVD conditions include a temperature range about 300° C. and about 600° C. Deposition time is about 10 seconds to about 500 seconds, for example between about 20 seconds to about 120 seconds. The reactant NH₃:SiH₄ gas ratio may be in a ration about 4:1 to about 10:1, for example less than about 8:1. Alternative reactants include a di-saline:NH₃ gas ratio in a range from about 1:4 to about 1:10. The deposition pressure is preferably about 1.0 Torr to about 1.5 Torr. The PECVD power used to form the first stress dielectric layer 320 is preferably from about 1000 W to 2000 W.

The first stress dielectric layer 320, when tensile, may include silicon nitride, tetraethylorthosilicate (TEOS), silicon oxynitride (SiON), oxide, Si-rich nitride, or a N-rich nitride, and it is preferably SiN or SiON. The first stress dielectric layer 320 may be deposited by rapid thermal chemical vapor deposition (RTCVD). The RTCVD temperature is 350° C. to about 800° C., from example between about 400° C. and about 700° C. Reaction time is about 10 seconds to about 2000 seconds, for example between about 20 seconds and about 120 seconds. The NH₃:SiH₄ gas ratio is about 50:1 to about 400:1, and for example between about 700:1. An alternative reactant composition includes a di-saline:NH₃ gas ratio about 1:40 to about 1:500. The deposition pressure is preferably about 10 Torr to about 400 Torr.

In operation 208, a second passivation layer 322 is formed over the first stress dielectric layer 320, as shown in FIG. 3D. The second passivation layer 322 is sometimes referred to as passivation-2 or pass-2.

The second passivation layer 322 is deposited as a blanket layer. In accordance with some embodiments, second passivation layer 322 is formed of or comprises an inorganic dielectric material, which may include, and is not limited to, silicon nitride, silicon oxide, silicon oxy-nitride, silicon oxy-carbide, or the like, combinations thereof, or multi-layers thereof. The material of second passivation layer 322 may be the same or different from the first passivation layer 316. The deposition may be performed through a conformal deposition process such as ALD, CVD, or the like.

In operation 210, a second stress dielectric layer 324 is deposited on second passivation layer 322, as shown in FIG. 3E. The second stress dielectric layer 324 may be similar to the first stress dielectric layer 320. As discussed above, a stress level of the second stress dielectric layer 324 corresponds to the measured warpage. The second stress dielectric layer 324 is formed to create desirable stress and transfer the stress to the underlying features/layers. When the measured warpage indicates that the device substrate 300 needs warpage correction, the second stress dielectric layer 324 may be formed with a stress level to reduce warpage by imparting a stress/strain in the device substrate 300, thus, functioning as a warpage correction film. When the measured warpage indicates that the device substrate 300 does not need warpage correction, the second stress dielectric layer 324 may be formed with normal stress so that the second stress dielectric layer 324 to function as an etch stop layer for in subsequent processes. The second stress dielectric layer 324 may be a compressive stress film or a tensile stress film according to warpage correction needs. The stress level may be tuned by changing one or more of process factors, including but not limited to, composition, thickness, processing conditions, such as plasm power, pressure, temperature, and the like. The second stress dielectric layer 324 may comprise a single layer or a plurality of layers. The second stress dielectric layer 324 may be formed by the similar process as described in operation 206.

In operation 212, openings 326 are formed through the second stress dielectric layer 324, the second passivation layer 322, and the first stress dielectric layer 320 to expose the conductive pad 318 for packaging process, as shown in FIG. 3F. After formation the opening 326, the device substrate 300 may be diced to individual dies for packaging. During subsequent packaging, for example in a SoC packaging scheme, solder pumps may be formed in the openings 326 to connect with the device layer 308. Alternatively, a planar layer may be formed over the second dielectric layer 324 for other packaging scheme, for example to vertically stacked with another die. At this stage a RDL structure 307 is formed.

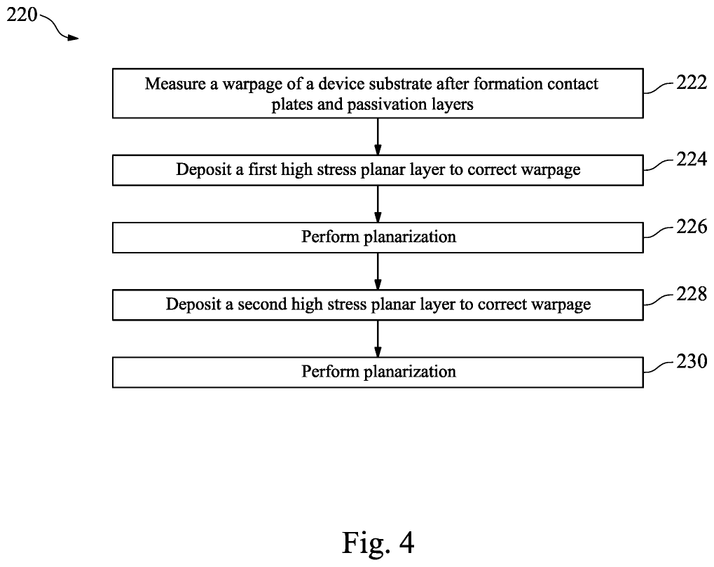

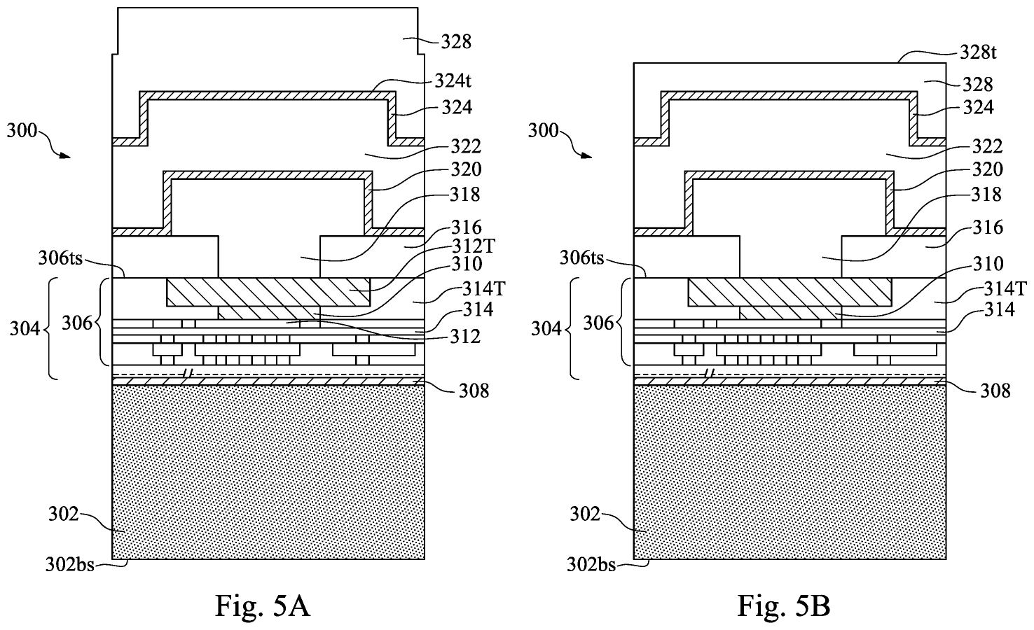

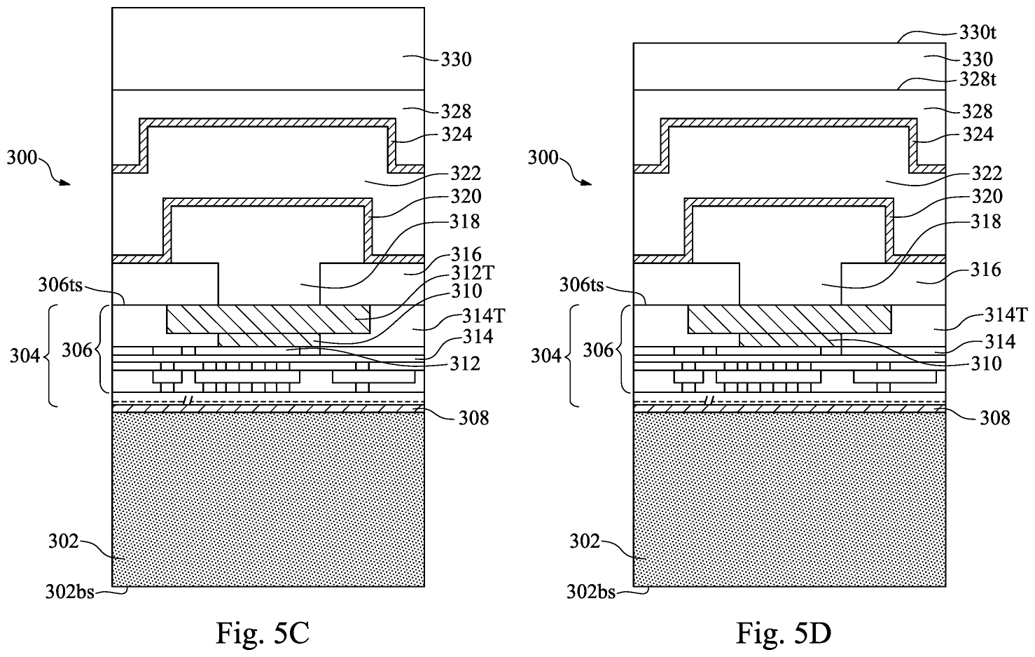

FIG. 4 is a flow chart of a method 220 for correcting warpage using a front side stress layer. FIGS. 5A-5D are schematic partial cross section of a device substrate 300 at various stages forming a front side stress layer according to method 220.

In operation 222, warpage of the device substrate 300 is measured. As shown in FIG. 5A, the device substrate 300 includes the device portion 304 formed on the substrate 302, and conductive pads 318 formed in the passivation layers 316 and 320. In some embodiments, the device substrate 300 may be formed according to the method 200 described above and further include the dielectric layers 320, 324 formed on the passivation layers 316, 320. In some embodiments, the dielectric layers 320, 324 may be formed to correct warpage. Alternatively, the dielectric layers 320, 324 are normal etch stop layers without warpage correction stress.

The device substrate 300 has a top surface 324t resulting from depositing the dielectric layer 324. In some embodiments, the amount and direction of warpage may be measured by a maximum distance between the top surface 324 or the back surface 302bs the device substrate 300 deviates from a horizontal plane. In some embodiments, warpage measurement may be performed in line, for example using probes in processing chambers or tools. In some embodiments, the warpage measurement may be used to determine die level warpage. If the measured die level warpage is greater than the warpage tolerance of the corresponding packaging scheme. In some embodiments, characteristics of the subsequently formed planar film are determined according to the measured warpage so that the die level warpage is within the warpage tolerance.

In operation 224, a first planar layer 328 over the dielectric layer 324, as shown in FIG. 5A. To fabricate circuit dies that subsequently stacked with other circuit dies, one or more planarization layers may be formed over passivation layers 322. The first planar layer 328 may be a stress layer having a stress level corresponding to the measured warpage in operation 222. The f first planar layer 328 is formed to create desirable stress and transfer the stress to the underlying features/layers. When the measured warpage indicates that the device substrate 300 needs warpage correction, the first planar layer 328 may be formed with a stress level to reduce warpage by imparting a stress/strain in the device substrate 300, thus, functioning as a warpage correction film. When the measured warpage indicates that the device substrate 300 does not need warpage correction, the first planar layer 328 may be formed with normal stress so that the first planar layer 328 only functions to provide a planarized top surface.

In some embodiments, the first planar layer 328 may be a dielectric layer, for example, the first planar layer 328 comprise SiO₂, SiOC, SiON, or the like. The first planar layer 328 is formed to have a planar top surface in the resulting device substrate 300. The first planar layer 328 may be formed by suitable deposition process, such as Plasma Enhanced Chemical Vapor Deposition (PECVD), High Density Plasma Chemical Vapor Deposition (HDPCVD), spin-coating, Flowable Chemical Vapor deposition (FCVD), or the like.

In some embodiments, the first planar layer 328 may be an oxide-based dielectric such as silicon oxide, for example, silicon oxide may be formed of TEOS. The formation method may include Chemical Vapor Deposition (CVD), High-Density Plasma Chemical Vapor Deposition (HDPCVD), or the like. In some embodiments, the planar layer 328 may be formed with stress designed to correct warpage. The stress may be introduced by tuning process parameters, such as plasma power.

In operation 226, a planarization process, such as CMP, is performed to obtain a planar top surface 228t, as shown in FIG. 5B. In situations that the first planar layer 328 is a warpage correction film, the planarization process reduces the thickness of the planar layer 328, therefore, also reduces effectiveness of the warpage correction. In some embodiments, additional planar layer may be formed.

In operation 228, a second planar layer 330 is formed on the planar top surface 328t, as shown in FIG. 5C. Similar to the first planar layer 328, the second planar layer 330 may be a stress layer with a stress level corresponding to the warpage. The second planar layer 330 and the first planar layer 328 may be formed from the same or different materials. In some embodiments, the second planar layer 330 includes a dielectric layer. The second planar layer 330 may be an oxide-based dielectric such as silicon oxide, for example, silicon oxide may be formed of TEOS. The formation method may include Chemical Vapor Deposition (CVD), High-Density Plasma Chemical Vapor Deposition (HDPCVD), or the like. In some embodiments, the second planar layer 328 may be formed with stress designed to correct warpage. The stress may be introduced by tuning process parameters, such as plasma power.

In operation 230, a planarization process, such as CMP, is performed to obtain a planar top surface 230t, as shown in FIG. 5D. In situations that the second planar layer 330 is a warpage correction film, the planarization process may terminate at a thickness that enables the second planar layer 330 to achieve desired warpage correction.

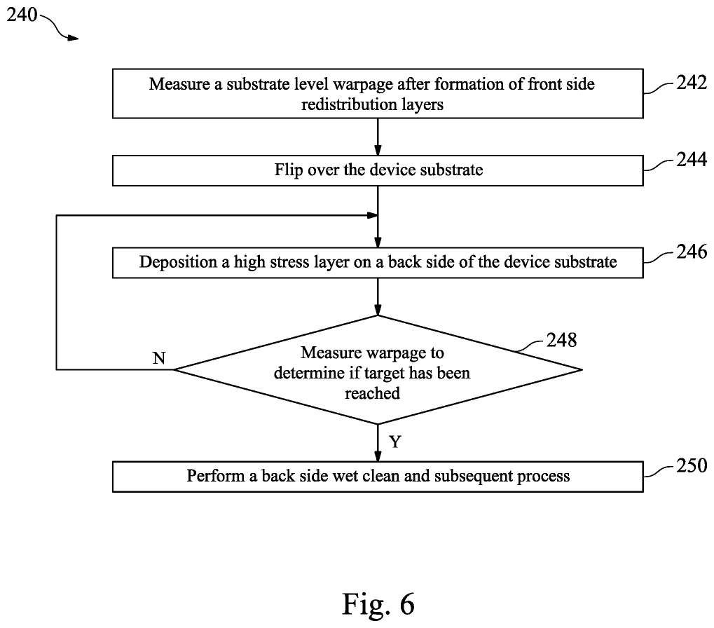

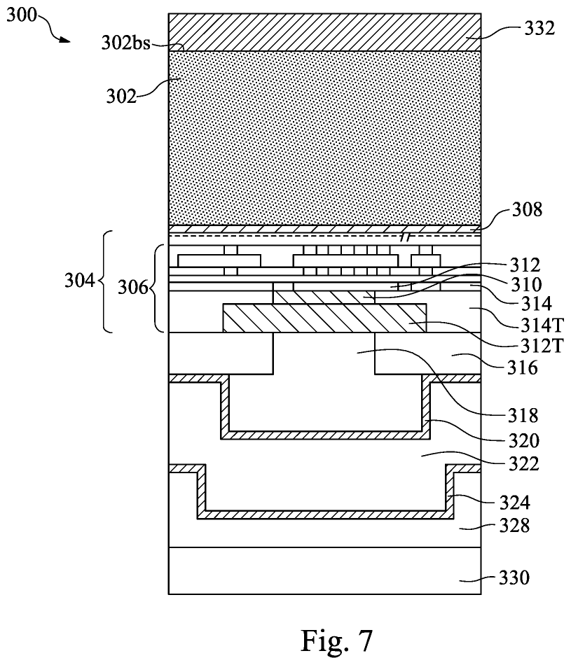

FIG. 6 is a flow chart of a method 240 for correcting warpage using a back side stress layer. FIG. 7 is schematic partial cross section of the device substrate 300 with a back side stress layer 332 formed according to the method 240. Prior to forming the back side stress layer 332 is formed, the device substrate 300 may be as shown in FIG. 3F or FIG. 5D. The device substrate 300 includes the device portion 304 formed on the substrate 302, and conductive pads 318 formed in the passivation layers 316 and 320, and optionally the planar layers 328, 330. In some embodiments, the device substrate 300 may be formed according to the method 200 described above and further include the dielectric layers 320, 324 formed on the passivation layers 316, 320. In some embodiments, the device substrate 300 may be formed according to the method 220 described above and further include the planar layers 328, 330. In some embodiments, some or all of the dielectric layers 320, 324 and the planar layers 328, 330 may be formed to correct warpage. Alternatively, the dielectric layers 320, 324 are conventional etch stop layers without warpage correction and the planar layers 328, 330 are conventional planar layers without warpage correction.

In operation 242, warpage of the device substrate 300 is measured. The warpage measurement may be used to determine properties, such as thickness and stress level, of the back side stress layer 332.

In operation 244, a carrier wafer may be attached to the top surface 330t or 324t and the device substrate 300 is flipped over to process on the back surface 302t.

In operation 246, the back side stress layer 332 is deposited on the back side 302b of the substrate 302, as shown in FIG. 7. The back side stress layer 332 may be a dielectric material, such as silicon nitride (Si₃N₄ or SiN), tetraethylorthosilicate (TEOS), silicon oxide, silicon oxynitride (SiON), Si-rich silicon nitride, a N-rich silicon nitride, or other suitable material. In some embodiments, the back side stress layer 332 may be, polyimide, glass, plastic, ceramic, molding compound, and the like. In some embodiments, the back side stress layer 332 a conductive material such as nickel, chromium, or the like.

In some embodiments, the back side stress layer 332 may comprise silicon nitride. Stoichiometric silicon nitride films are known to be highly tensile stressed on silicon. In some embodiments, the tensile stress may be greatly lowered and even turned into compressive stress by adjusting the film density. For example, SiNₓ thin films are prepared using three types of PECVD conditions to induce tensile (T-SiNₓ), neutral (N—SiNₓ), and compressive (C—SiNₓ) residual stress. Compared with the T-SiNₓ thin films (77 GPa, 0.10%, and 83 MPa, respectively), the C—SiNₓ thin films shows an approximately 45% increase in Young's modulus (112 GPa), a twofold enhancement of the elongation (0.21%), and a threefold improvement in the fracture strength (226 MPa). Thus, C—SiNₓ thin films have improved intrinsic mechanical properties. In some embodiments, higher RF power, lower chamber pressure, and/or lower NH₃ feed ratios are used to deposition C—SiNₓ thin films increase film density, for example from, 2.42-2.64 g/cm³, and reduce dangling H of the N—H bonding. In some embodiments, may have a thickness in a range between about 100 nm and 2000 nm.

In operation 248, warpage measurement is performed to check if warpage of the device substrate 300 has been corrected to within the tolerance. If the warpage not within the tolerance, the operations 246 and 248 may be repeated, until the warpage is within the tolerance.

In operation 250, a wet cleaning and subsequent process may be performed. For example, a stressed bond film may be deposited and the device substrate 300 may be diced into individual dies for packaging.

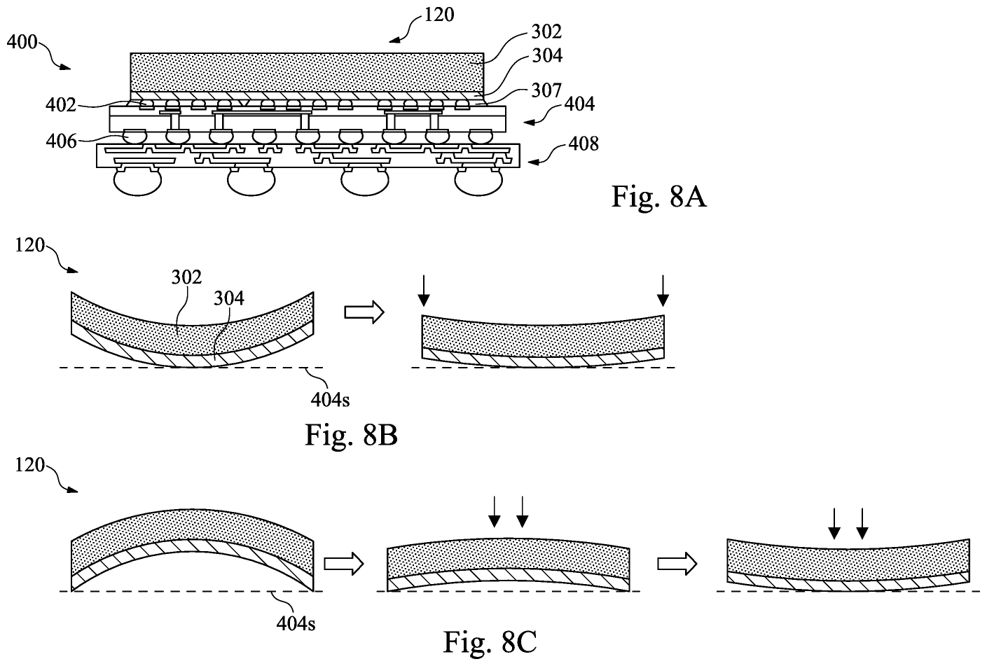

Depending on packaging scheme, and actual warpage, the methods 200, 220, 240 may be used alone or in combination to correct warpage. FIGS. 8A-8C, 9A-9D, and 10A-10D are exemplary packaging schemes and corresponding warpage corrections.

FIG. 8A is a package structure 400 formed by a system on chip (SOC) packaging scheme. The package structure 400 includes a die 120, such as an individual die from the device substrate 300 in FIG. 3F. The die 120 may include the substrate 302, the device portion 304, and the RDL structure 307 formed on the device portion 304. The die 120 is bond to an interposer substrate 404 via external contacts 402 formed in the openings 326 of the RDL structure 307. The interposer substrate 404 is then connected to a package substrate 408 via connectors 406. The package substrate 408 may be a printed circuit board (PCB). In the package structure 400, one or more dies 120 are arranged in a planar arrangement. In the package structure 400, the front side of the die 120 is bond to a surface 404s of the interposer substrate 404. To obtain quality bonding between the die 120 and the interposer substrate 404, warpage the die 120 needs to be within a critical value. As discussed above, the die 120 may be warped due to the composition and process. In some embodiments, the method 200 may be used to correct warpage.

FIGS. 8B and 8C are schematically illustrate warpage correction plans for the SOC packaging scheme of the package structure 400. In FIG. 8B, the die 120 has a positive warpage. To improve bonding quality, one or more warpage correction films, such as the dielectric layers 320, 324 may be used to reduce the positive warpage. In FIG. 8C, the die 120 has a negative warpage. To improve bonding quality, one or more warpage correction films, such as the dielectric layers 320, 324 may be used to reduce the negative warpage. During bonding process, the die 120 is bonding to the interposer substrate 404 from a center region towards edge regions. A negative warpage may cause air bubbles in the bonding, therefore, not desirable. In some embodiments, a negatively warped die 120 may be corrected to a positive warp to avoid formation of air bubbles.

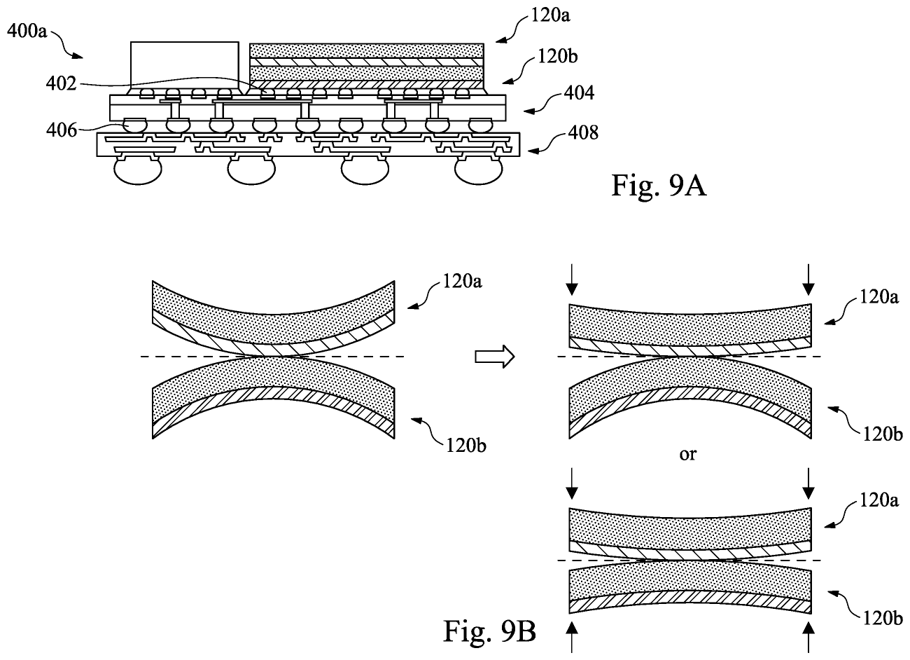

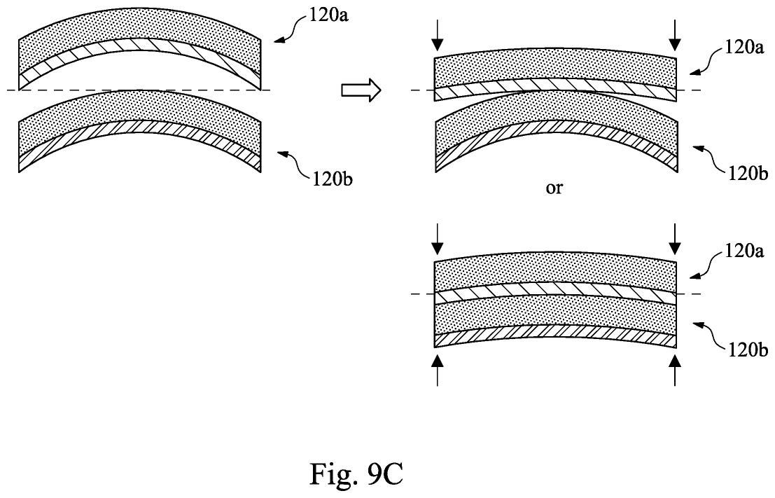

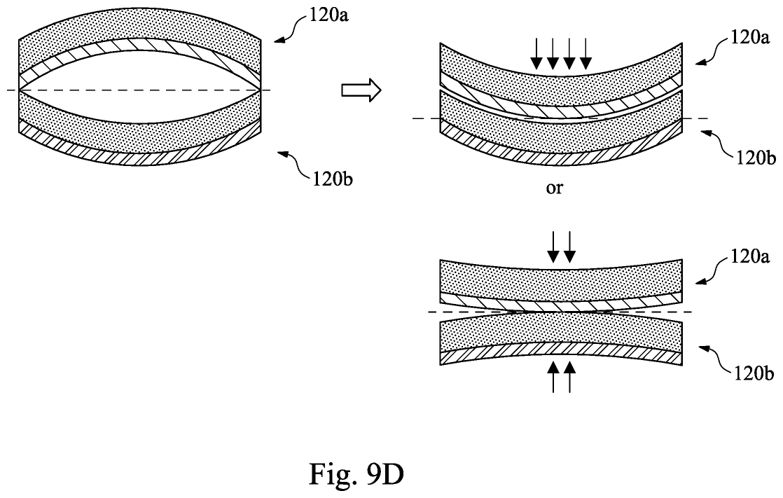

FIG. 9A is a package structure 400a formed by a SoIC (an integrated SOC) packaging scheme. The package structure 400a includes two dies 120a, 120b vertically stacked. In the package structure 400a, the front side of the die 120a is bond to the back side of the die 120b. The front side of the die 120b is bond to the interposer. The dies 120a, 120b may be individual die from the device substrate 300 as shown in FIG. 5D and FIG. 7. In some embodiments, one or more of the methods 200, 220, and 240 may be used to correct warpage at the substrate level during fabrication of the dies 120a, 120b.

FIGS. 9B-9D are schematically illustrate warpage correction plans for the SoIC packaging scheme. In FIG. 9B, the die 120a has a positive warpage, the die 120b has a negative warpage, and the dies 120a, 120b are first contact at the center when positioned against each other. To improve bonding quality, at least one of the dies 120a, 120b may include warpage correction films according to the present disclosure. In FIG. 9C, both of the dies 120a, 120b have a negative warpage. To improve bonding quality, at least one of the dies 120a, 120b may include warpage correction films according to the present disclosure. In some embodiments, after corrections, the die 120b may have a greater warpage than the die 120a so that the dies 120a, 120b are first contact at the center when bonding. In FIG. 9D, the die 120a has a negative warpage, the die 120b has a positive warpage, and the dies 120a, 120b are first contact at edge regions when positioned against each other. To improve bonding quality, at least one of the dies 120a, 120b may include warpage correction films according to the present disclosure. In some embodiments, the die 120a may be corrected from negative warpage to positive warpage.

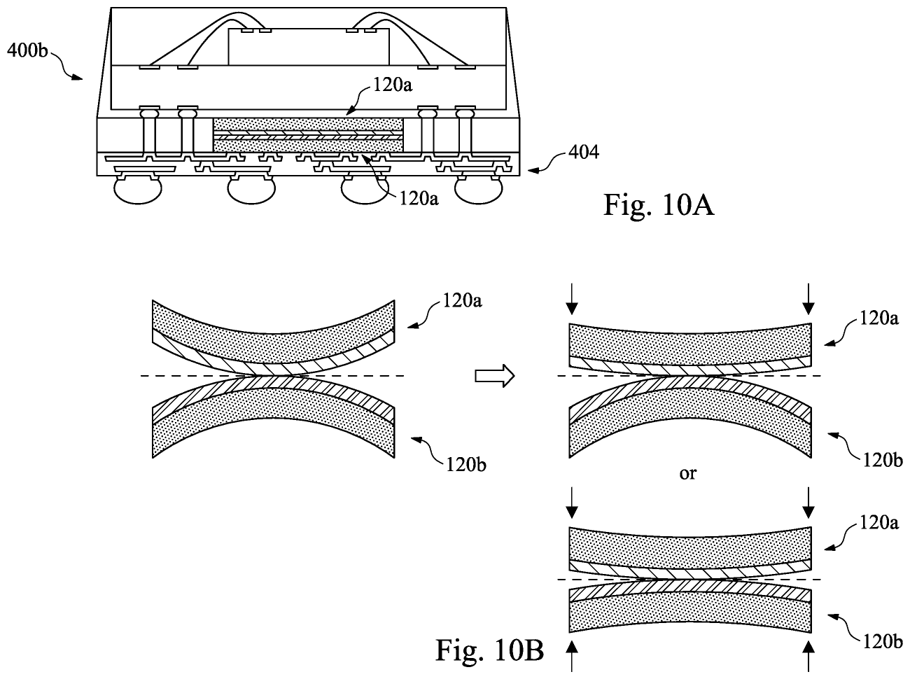

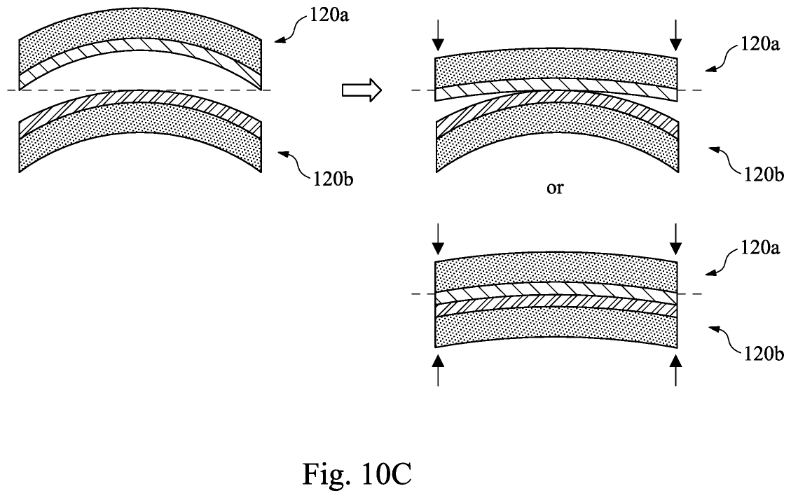

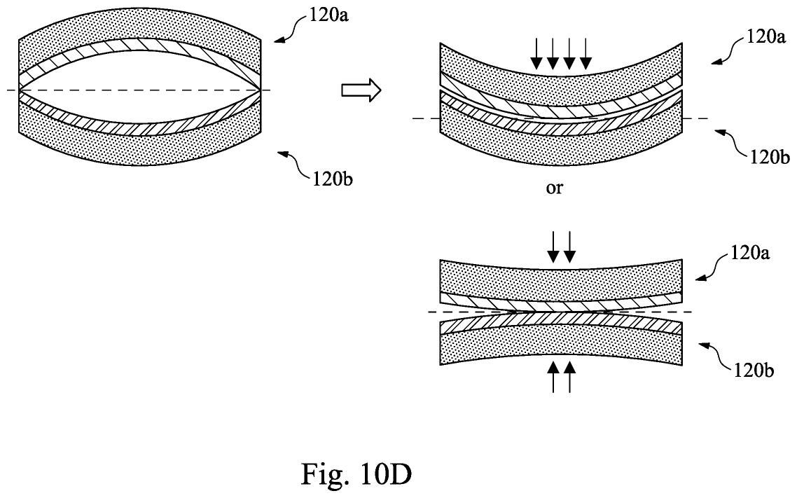

FIG. 10 is a package structure 400b formed by a SoIC (an integrated SOC) packaging scheme. The package structure 400b includes two dies 120a, 120b vertically stacked. In the package structure 400b, the front side of the die 120a is bond to the front side of the die 120b. The dies 120a, 120b may be individual die from the device substrate 300 as shown in FIG. 5D and FIG. 7. In some embodiments, one or more of the methods 200, 220, and 240 may be used to correct warpage at the substrate level during fabrication of the dies 120a, 120b.

FIGS. 10B-10D are schematically illustrate warpage correction plans for the SoIC packaging scheme. In FIG. 10B, the die 120a has a positive warpage, the die 120b has a positive warpage, and the dies 120a, 120b are first contact at the center when positioned against each other. To improve bonding quality, at least one of the dies 120a, 120b may include warpage correction films according to the present disclosure. In FIG. 10C, the die 120a has a negative warpage, the die 120b has a positive warpage. To improve bonding quality, at least one of the dies 120a, 120b may include warpage correction films according to the present disclosure. In FIG. 10D, the die 120a has a negative warpage, the die 120b has a negative warpage, and the dies 120a, 120b are first contact at edge regions when positioned against each other. To improve bonding quality, at least one of the dies 120a, 120b may include warpage correction films according to the present disclosure. In some embodiments, the die 120a may be corrected from negative warpage to positive warpage.

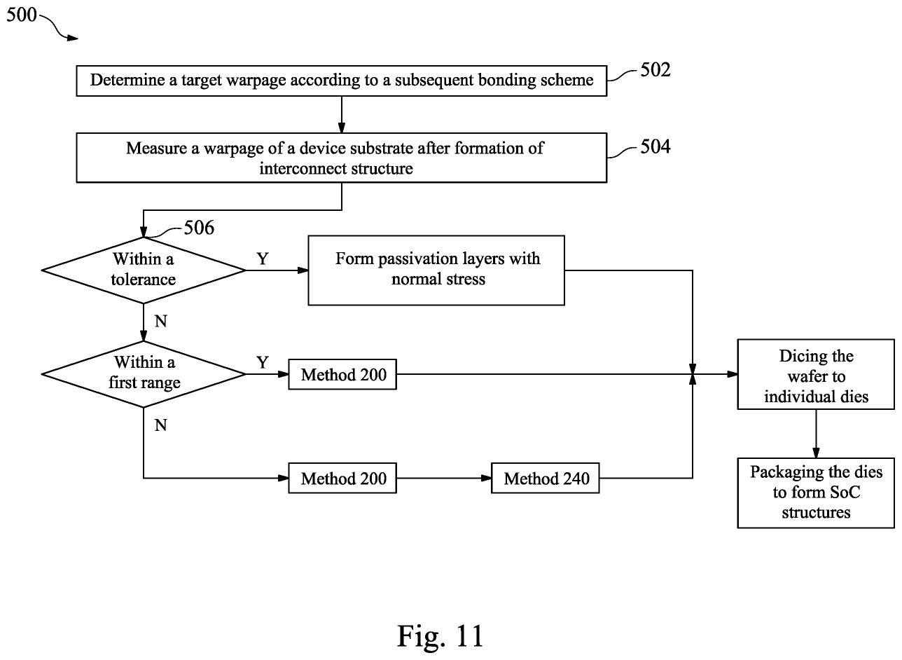

FIG. 11 is flow chart of a method 500 for automatic process of warpage correction at substrate level for dies to be packaged with a SOC packaging scheme. In operation 502 of the method 500, a target warpage of a device substrate is determined according to the bonding scheme, such as the bonding schemes shown in FIGS. 8B-8C. In operation 504, warpage of the device substrate is measured prior to forming a RDL structure over the interconnect structure. In operation 506, the measured warpage is then compared to the target warpage. If the difference between the target warpage and the measured warpage is within the tolerance, the RDL structure is formed with dielectric layers of normal stress. If the difference between the target warpage and the measured warpage is greater than the tolerance but within a first range, the RDL structure is formed using the method 200 with warpage correcting films in the RDL structure. If the difference between the target warpage and the measured warpage is greater than the small range, the RDL structure is formed using the method 200 with warpage correcting films in the RDL structure, and the method 240 to form back side stress layer. The device substrate is then diced and packaged into SoC structures.

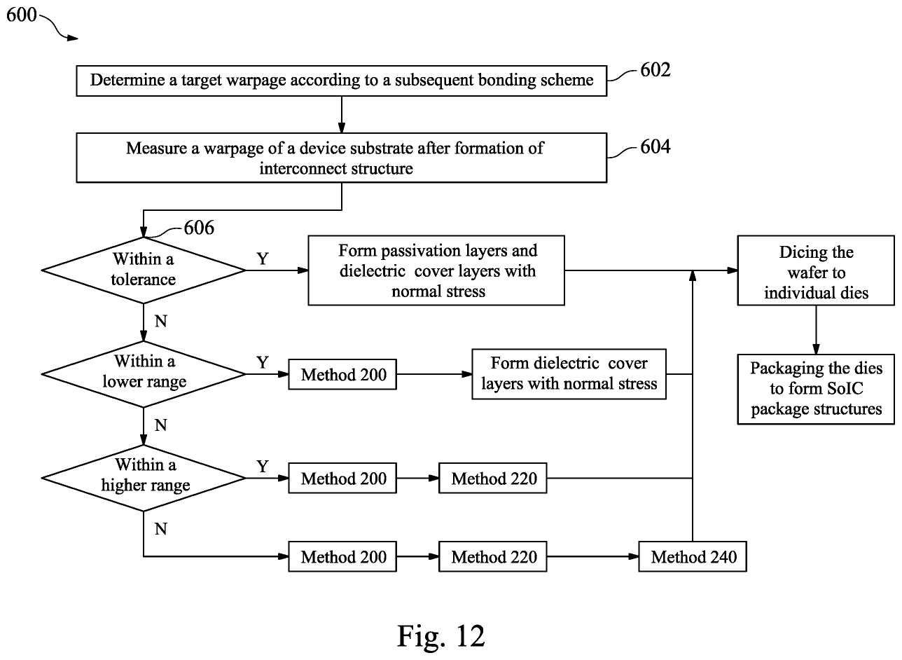

FIG. 12 is flow chart of a method 600 for warpage correction at substrate level for dies to be packaged with a SIoC packaging scheme. In operation 602 of the method 600, a target warpage of a device substrate is determined according to the bonding scheme, such as the bonding schemes shown in FIGS. 9B-9D and FIGS. 10B-10D. In operation 604, warpage of the device substrate is measured prior to forming a RDL structure over the interconnect structure. In operation 606, the measured warpage is then compared to the target warpage. If the difference between the target warpage and the measured warpage is within the tolerance, the RDL structure and the planar layers are formed with dielectric layers of normal stress. If the difference between the target warpage and the measured warpage is greater than the tolerance but within a lower range, the RDL structure is formed using the method 200 with warpage correcting films in the RDL structure and the planar layers may be formed with normal stress. Alternatively, the RDL structure may be formed with normal stress and the planar layers formed with warpage correction films using the method 220. If the difference between the target warpage and the measured warpage is greater than the small range and lower than the higher range, the RDL structure is formed using the method 200 with warpage correcting films in the RDL structure and the planar layers formed with warpage correction films using the method 220. If the difference between the target warpage and the measured warpage is greater than the higher range, the RDL structure is formed using the method 200 with warpage correcting films in the RDL structure, the planar layers formed with warpage correction films using the method 220, and the method 240 to form back side stress layer. The device substrate is then diced and packaged into SoIC structures.

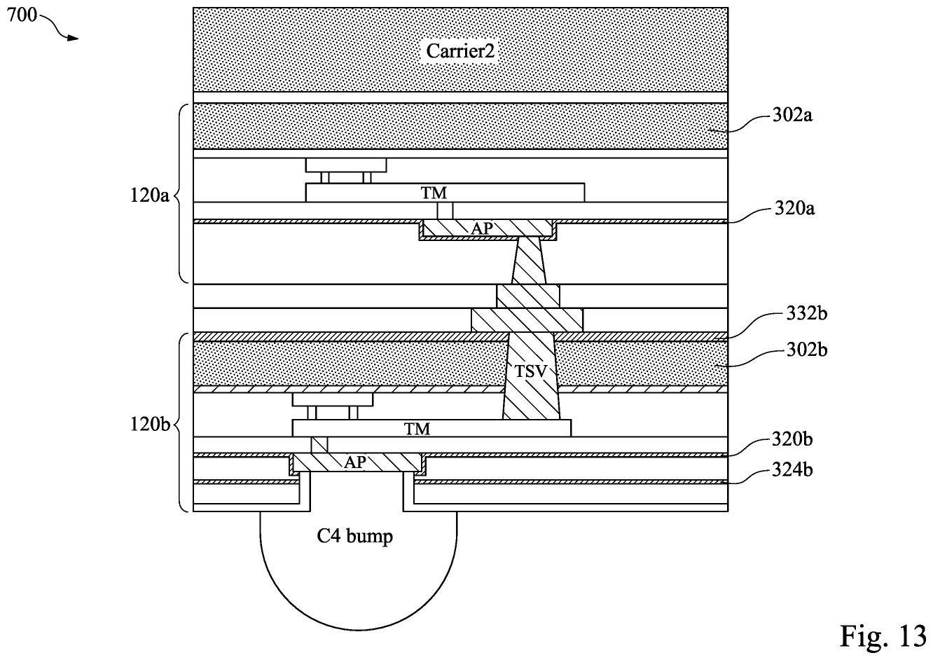

FIG. 13 is a schematic cross sectional view of a SoIC package structure 700 including dies 120a, 120b with warpage correcting high stress films according to embodiments of the present disclosure. In the package structure 700, the front side of the die 120a is bond to the back side of the die 120b. The front side of the die 120b includes external contacts and subsequently connect to an interposer substrate. The die 120a includes a silicon nitride containing warpage correction film 320a in the RDL structure. The die 120b includes a backside warpage correction film 332b, and silicon nitride containing warpage correction film 320b, 324b in the RDL structure.

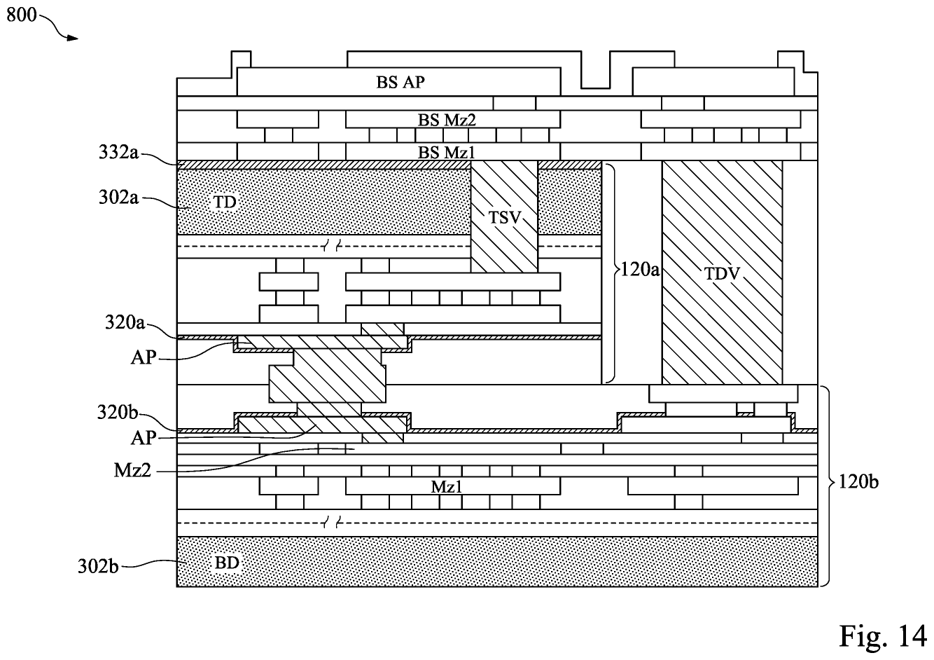

FIG. 14 is a schematic cross sectional view of a SoIC package structure 800 including dies 120a, 120b with warpage correcting high stress films according to embodiments of the present disclosure. In the package structure 800, the front side of the die 120a is bond to the front side of the die 120b. The back side of the die 120a is connected to a backside interconnect structure. The die 120a includes a silicon nitride containing warpage correction film 320a in the RDL structure and a backside warpage correction film 332a. The die 120b includes a silicon nitride containing warpage correction film 320b in the RDL structure

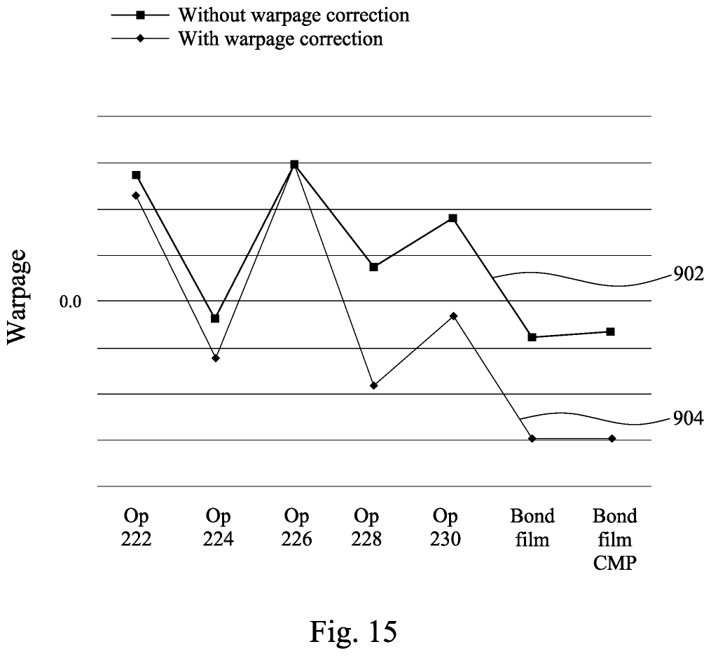

FIG. 15 is a schematic plot warpage measurement during warpage correction according to embodiments of the present disclosure. Particularly, FIG. 15 includes warpage measures of the forming planar layers on RLD. Plot 902 shows warpage measurements of forming planar layers without warpage correction. Plot 904 includes warpage measurements with warpage correction using the method 220. Comparison of plots 902 and 904 demonstrates that the substrate level warpage is effectively adjusted using embodiments of the present disclosure.

Various embodiments or examples described herein offer multiple advantages over the state-of-art technology. The warpage correction methods according to the present disclosure ensures a high SoIC bonding yield, reduces dielectric crack risk caused by un-expected warpage change. Embodiments of the present disclosure allows fine tuning of warpage at substrate level. Embodiments of the present disclosure also keeps higher FEOL/BEOL device integrity through SoIC process.

It will be understood that not all advantages have been necessarily discussed herein, no particular advantage is required for all embodiments or examples, and other embodiments or examples may offer different advantages.

Some embodiments of the present provide a method for correcting warpage, comprising: measuring a substrate level warpage prior to forming a RDL structure on a substrate; determining a difference between the measured warpage and a target warpage; and performing a substrate level warpage correction if the difference is greater than a tolerance, wherein the substrate level warpage correction includes at least one of: forming a warpage correction layer in the RDL structure; forming a front side warpage correction layer over the RDL structure; and forming a back side warpage correction layer.

Some embodiments of the present disclosure provide a method for correcting warpage, comprising determining a die level warpage tolerance according to a packaging scheme; determining a target substrate level warpage according to the die level warpage; measuring a substrate level warpage of a substrate having a device layer and an interconnect structure formed on a front side of the substrate; determining characteristics of a warpage correction layer according to the substrate level warpage; forming the warpage correction layer, wherein the warpage correction layer includes one of a stress dielectric layer in the RDL structure over the interconnect structure, a front side dielectric planar layer over the RDL layer, and a back side stress layer on a back side of the substrate; and dicing the substrate to individual dies.

Some embodiments of the present disclosure provide a package structure, comprising: a first die structure, comprising: a first substrate; a first device layer formed over a front side of the first substrate; a first interconnect structure formed over the first device layer; a first RDL structure formed over the first interconnect structure; and a back side warpage correction film formed on a backside of the first substrate; and a second die structure bond to the first die structure, wherein the second die structure comprises: a second substrate; a second device layer formed over a front side of the second substrate; a second interconnect structure formed over the second device layer; and a second RDL structure formed over the second interconnect structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method for correcting warpage, comprising:
measuring a substrate level warpage prior to forming a RDL structure on a substrate;
determining a difference between the measured warpage and a target warpage; and
performing a substrate level warpage correction if the difference is greater than a tolerance, wherein the substrate level warpage correction includes at least one of:
forming a warpage correction layer in the RDL structure;
forming a front side warpage correction layer over the RDL structure; and
forming a back side warpage correction layer.

2. The method of claim 1, further comprising: determining characteristics of the warpage correction layer, the front side warpage correction layer, or the back side warpage correction layer according to the difference between the measured warpage and a target warpage.

3. The method of claim 1, wherein forming the warpage correction layer in the RDL structure comprises:
depositing a first passivation layer;
depositing a first warpage correction layer on the first passivation layer;
depositing a second passivation layer on the first warpage correction layer; and
depositing a second warpage correction layer on the second passivation layer.

4. The method of claim 3, further comprising: forming an opening through the first warpage correction layer, the second passivation layer and the second warpage correction layer.

5. The method of claim 1, wherein forming the front side warpage correction layer comprises:
depositing a first planar layer on the second warpage correction layer, wherein the first planar layer;
performing a first planarization process;
depositing a second planar layer on the planarized first planar layer; and
performing a second planarization process.

6. The method of claim 1, wherein forming the back side warpage correction layer comprises:
depositing a first back side stress layer on the back side of the substrate;
measuring warpage after depositing the back side stress layer; and
depositing a second back side stress on the first back side stress layer if the measured warpage is greater than a tolerance.

7. The method of claim 2, wherein performing the substrate level warpage correction comprises:
if the difference is less than a first range,
forming the warpage correction layer in the RDL structure;
if the difference is greater than the first range,
forming the warpage correction layer in the RDL structure; and
forming the front side warpage correction player.

8. The method of claim 7, wherein performing the substrate level warpage correction comprises:
if the difference is greater than a second range, wherein the second range is greater than the first range,
forming the back side warpage correction player.

9. A method for correcting warpage, comprising:
determining a die level warpage tolerance according to a packaging scheme;
determining a target substrate level warpage according to the die level warpage;
measuring a substrate level warpage of a substrate having a device layer and an interconnect structure formed on a front side of the substrate;
determining characteristics of a warpage correction layer according to the substrate level warpage;
forming the warpage correction layer, wherein the warpage correction layer includes one of a stress dielectric layer in the RDL structure over the interconnect structure, a front side dielectric planar layer over the RDL layer, and a back side stress layer on a back side of the substrate; and
dicing the substrate to individual dies.

10. The method of claim 9, wherein forming the warpage correction layer comprises forming a first stress dielectric layer on a first passivation layer in the RDL structure.

11. The method of claim 10, wherein forming the warpage correction layer comprises further forming a second stress dielectric layer on a second passivation layer in the RDL structure.

12. The method of claim 11, wherein forming the warpage correction layer further comprises forming one or more planar layer on the second stress dielectric layer.

13. The method of claim 9, wherein forming the warpage correction layer comprises:
depositing a first back side stress layer on the back side of the substrate.

14. The method of claim 13, wherein forming the warpage correction layer comprises:
measuring warpage after depositing the back side stress layer; and
depositing a second back side stress on the first back side stress layer if the measured warpage is greater than a tolerance.

15. A package structure, comprising:
a first die structure, comprising:
a first substrate;
a first device layer formed over a front side of the first substrate;
a first interconnect structure formed over the first device layer;
a first RDL structure formed over the first interconnect structure; and
a back side warpage correction film formed on a backside of the first substrate; and
a second die structure bond to the first die structure, wherein the second die structure comprises:
a second substrate;
a second device layer formed over a front side of the second substrate;
a second interconnect structure formed over the second device layer; and
a second RDL structure formed over the second interconnect structure.

16. The package structure of claim 15, wherein a front side of the first die structure is bond to a front side of the second die structure.

17. The package structure of claim 16, wherein the first die structure further comprises a first warpage correction film in the first RDL structure, and the second die structure further comprises a second warpage correction film in the second RDL structure.

18. The package structure of claim 15, wherein the back side warpage correction film of the first die structure is bond to a front side of the second die structure.

19. The package structure of claim 18, wherein the first die structure further comprises a first warpage correction film in the first RDL structure, and the second die structure further comprises a second warpage correction film in the second RDL structure.

20. The package structure of claim 19, wherein the first die structure further comprises a third warpage correction film in the first RDL structure.
